(19) United States
(12) Patent Application Publication
(10) Pub. No.: US 2026/0301782 A1
(43) Pub. Date: Oct. 1, 2026

(54) MEMORY MODULE AND ELECTRONIC DEVICE

(71) Applicant: CXMT Corporation, Hefei (CN)

(72) Inventors: Shengbao Liao, Hefei (CN); Lin Wu, Hefei (CN)

(73) Assignee: CXMT Corporation, Hefei (CN)

(21) Appl. No.: 19/418,253

(22) Filed: Dec. 12, 2025

Related U.S. Application Data
(63) Continuation of application No. PCT/CN2025/134847, filed on Nov. 14, 2025.

(30) Foreign Application Priority Data
Mar. 26, 2025 (CN) 202510377030.2

(51) Int. Cl. G11C 7/04; G11C 5/06; G11C 11/4093

(52) U.S. Cl. CPC G11C 7/04; G11C 5/063; G11C 11/4093

(57) ABSTRACT

A memory module and an electronic device are provided. The memory module includes multiple memory chips and multiple groups of signal ports. Each of the memory chips implements signal input and output through a corresponding group of signal ports. The memory chip is electrically connected to each of the signal ports through an independent signal line, and some or all signal lines are connected in series to target resistors. A difference between a resistance value of each of the target resistors at a first temperature and a resistance value of the target resistor at a second temperature is less than or equal to a first preset value. The first temperature is a normal temperature, and the second temperature is a maximum value of an operating temperature indicated by the memory module. The resistance value of the target resistor does not vary greatly between the normal temperature and a high temperature.

### CROSS REFERENCE TO RELATED APPLICATIONS

This application is a continuation of International Patent Application No. PCT/CN2025/134847, field on Nov. 14, 2025, which claims the benefit of Chinese Patent Application No. 202510377030.2 titled “MEMORY MODULE AND ELECTRONIC DEVICE”, field with the China National Intellectual Property Administration (CNIPA) on Mar. 26, 2025, the disclosures of which are incorporated herein by reference in their entireties.

### TECHNICAL FIELD

Embodiments of the present disclosure relate to the field of integrated circuits, and in particular, to a memory module and an electronic device.

### BACKGROUND

A registered dual in-line memory module (Registered Dual In-Line Memory Module, RDIMM) is mainly employed in a high-performance computing environment such as a server and a workstation, and supports a larger memory capacity. The RDIMM often encounters a case with high loading (Loading). In this case, series resistors are employed on signal lines to absorb reflected signals and improve signal integrity. However, this approach introduces a heat generation problem, which in turn causes impedance mismatch and degrades signal transmission performance.

### SUMMARY

The present disclosure provides a memory module and an electronic device, to improve signal transmission integrity at a high temperature.

The technical solutions of the present disclosure are implemented as follows.

According to a first aspect, an embodiment of the present disclosure provides a memory module. The memory module includes multiple memory chips and multiple groups of signal ports. Each of the memory chips implements signal input and output through a corresponding group of signal ports. The memory chip is electrically connected to each of the signal ports through an independent signal line, and some or all signal lines are connected in series to target resistors. A difference between a resistance value of each of the target resistors at a first temperature and a resistance value of the target resistor at a second temperature is less than or equal to a first preset value. The first temperature is a normal temperature, and the second temperature is a maximum value of an operating temperature indicated by the memory module.

According to a second aspect, an embodiment of the present disclosure provides an electronic device. The electronic device includes the memory module according to the first aspect.

### BRIEF DESCRIPTION OF DRAWINGS

FIG. 1 and FIG. 2 are schematic diagrams of structures of a memory module in a related technology;

FIG. 3 is a schematic diagram 1 of a structure of a memory module according to an embodiment of the present disclosure;

FIG. 4 to FIG. 6 are schematic diagrams of structures of a target resistor according to an embodiment of the present disclosure;

FIG. 7 is a schematic diagram 2 of a structure of a memory module according to an embodiment of the present disclosure;

FIG. 8 is a schematic diagram of connection of a target resistor according to an embodiment of the present disclosure;

FIG. 9 is a schematic diagram of a structure of a memory module in a related technology;

FIG. 10 is a schematic diagram 3 of a structure of a memory module according to an embodiment of the present disclosure;

FIG. 11 is a schematic diagram of a back side of a circuit board of a memory module according to an embodiment of the present disclosure;

FIG. 12 to FIG. 15 are schematic diagrams of signal transmission simulation results of a memory module according to an embodiment of the present disclosure; and

FIG. 16 is a schematic diagram of a structure of an electronic device according to an embodiment of the present disclosure.

### DESCRIPTION OF EMBODIMENTS

The technical solutions of the present disclosure are further described below in detail with reference to the accompanying drawings and the embodiments. Although example implementation methods of the present disclosure are shown in the accompanying drawings, it should be understood that the present disclosure may be implemented in various forms without being limited by the implementations described herein. Instead, these implementations are provided to develop a more thorough understanding of the present disclosure and to fully convey the scope of the present disclosure to a person skilled in the art.

In the following paragraphs, the present disclosure is described more specifically by way of example with reference to the accompanying drawings. The advantages and features of the present disclosure will be clearer from the following description and claims. It should be noted that the accompanying drawings are presented in a highly simplified form and are not drawn to exact scale, and are merely intended to conveniently and clearly assist in describing the embodiments of the present disclosure.

It may be understood that meanings of “on”, “over”, and “above” in the present disclosure should be understood in the broadest sense, so that “on” means that it is “on” something with no intermediate feature or layer (that is, directly on something), and further includes the meaning that it is “on” something with an intermediate feature or layer.

In the embodiments of the present disclosure, the terms “first”, “second”, “third”, and the like are intended to distinguish between similar objects but do not necessarily describe a specific order or sequence.

In the embodiments of the present disclosure, the term “layer” refers to a material part including a region having the thickness. The layer may extend over the whole of a lower or upper structure, or may have a range smaller than the range of the lower or upper structure. In addition, the layer may be a region of a homogeneous or heterogeneous continuous structure whose thickness is less than the thickness of a continuous structure. For example, the layer may be located between the top surface and the bottom surface of the continuous structure, or the layer may be located between any horizontal surface pair at the top surface and the bottom surface of the continuous structure. The layer may extend horizontally, vertically, and/or along an inclined surface. The layer may include multiple sublayers.

It should be noted that the technical solutions described in the embodiments of the present disclosure may be arbitrarily combined when there is no conflict.
Dual in-line memory module (Dual In-Line Memory Module, DIMM);
Unbuffered DIMM (Unbuffered DIMM, UDIMM);
Registered DIMM (Registered DIMM, RDIMM);
LRDIMM (Load-Reduced DIMM, LRDIMM);
Non-volatile DIMM (Non-Volatile DIMM, NVDIMM);
Data center persistent memory module (Data Center Persistent Memory Module, DCPMM);
Dynamic random access memory (Dynamic Random Access Memory, DRAM);
Synchronous dynamic random access memory (Synchronous Dynamic Random Access Memory, SDRAM);
Double data rate SDRAM (Double Data Rate SDRAM, DDR);
Fifth-generation DDR (DDR5);
Low power DDR (Low Power DDR, LPDDR);
Static random access memory (Static Random Access Memory, SRAM);
Flash memory NAND;
Metal-oxide-semiconductor (Metal-Oxide-Semiconductor) MOS;
Mbps (megabits per second, Mbps); and
Ohm (ohm).

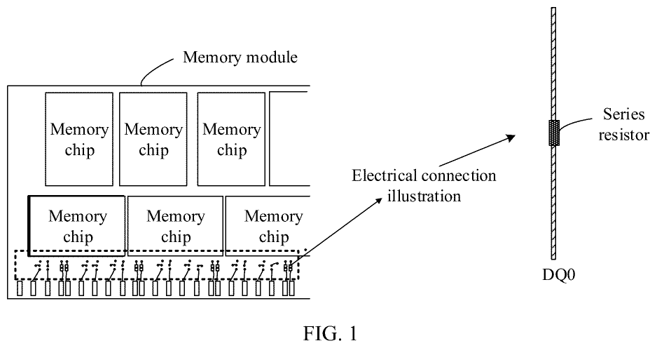

Referring to FIG. 1, which is a schematic diagram of a structure of a memory module. As shown in FIG. 1, the memory module is a RDIMM. The RDIMM includes a register and multiple chips (that is, memory chips, such as a DRAM, a DDR, and an LPDDR). There may be up to 40 chips on a DIMM. Data signals of the chips are transmitted to signal ports of the memory module through signal lines. There are series resistors on these signal lines, thereby implementing impedance matching. When the memory module operates at a full speed, the series resistors on the signal lines generate significant heat, particularly in a DDR5 with a high rate such as 5600 Mbps and 6400 Mbps as well as future DDR forms with even higher rates, resulting in high power consumption, and a rise in a temperature of the entire DIMM.

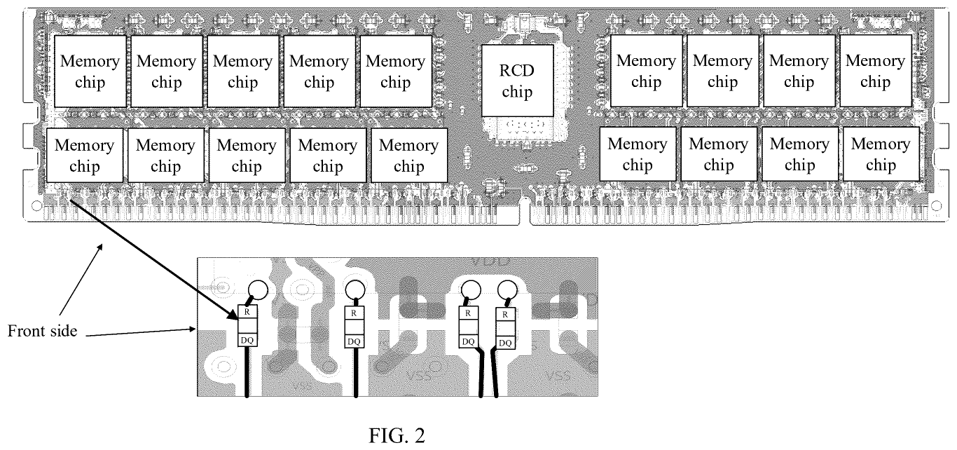

Referring to FIG. 2, which shows series resistors on DQ signal lines in the DIMM. The series resistors are at 15 ohms. When a temperature varies within a range of 25° C. to 100° C., due to temperature dependence of a dielectric constant and physical properties of a substrate material, direct current impedance of copper lines, and resistance values of the series resistors, impedance matching originally implemented at a normal temperature (25° C.) is damaged at a high temperature. Experiments show that each of the series resistors has a resistance value of 15 ohms at the normal temperature of 25° C., and a resistance value of 17.5 ohms at 100° C. This causes impedance mismatch at different temperatures and transmission performance alternation of the signal lines. In this case, accuracy of signal transmission at an extreme temperature cannot be ensured.

Overall, because a large quantity of memory chips are integrated on the RDIMM, when a rate is high, the series resistors on the data signal lines generate significant heat, and the overall temperature of the RDIMM rises. The resistance values of the series resistors increase because the temperature rises, causing signal integrity to be damaged at the high temperature.

Based on this, an embodiment of the present disclosure provides a memory module, to reduce a negative impact caused by temperature rising by connecting thermistors in parallel to the series resistor on the data signal lines, thereby ensuring signal transmission effectiveness.

The following describes the embodiments of the present disclosure in detail with reference to the accompanying drawings.

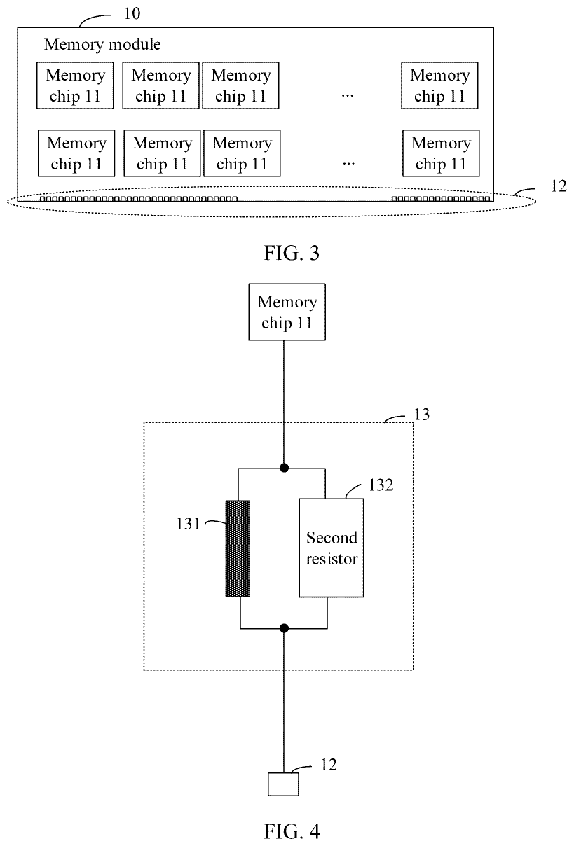

In an embodiment of the present disclosure, referring to FIG. 3, which is a schematic diagram of a structure of a memory module 10 according to an embodiment of the present disclosure. As shown in FIG. 3, the memory module 10 includes multiple memory chips 11.

It should be noted that each of the memory chips 11 in this embodiment of the present disclosure is a memory having a storage function. A basic structure of the memory chip 11 includes a memory array, an address decoder, a control circuit, and an input/output interface. The input/output interface is configured to transmit at least a command address signal and a data signal. The address decoder is configured to decode an address signal, and the control circuit is configured to read a data signal from the memory array or store a data signal into the memory array based on the command signal and the decoded address signal. The memory array has multiple memory cells, and these memory cells cell have a large quantity of specific structures, which can form different types of memory chips 11. The memory chips 11 include but are not limited to an SRAM, a DRAM, an SDRAM, a DDR, an LPDDR, and a NAND.

The memory module 10 is a module that integrates multiple memory chips 11, and may include but is not limited to a DIMM, a UDIMM, a RDIMM, an LRDIMM, an NVDIMM, a DCPMM, a single in-line memory module (Single In-Line Memory Module, SIMM), or a computing-in-memory module.

As shown in FIG. 3, the memory module 10 includes multiple groups of signal ports 12, and each of the memory chips 11 implements signal input and output through a corresponding group of signal ports 12.

The memory chip 11 is electrically connected to each of the signal ports 12 through an independent signal line, that is, an input/output port of the memory chip 11 is connected to a corresponding signal port 12 through the signal line, and some or all signal lines are connected in series to target resistors. A difference between a resistance value of each of the target resistors at a first temperature and a resistance value of the target resistor at a second temperature is less than or equal to a first preset value. The first temperature is a normal temperature, and the second temperature is a maximum value of an operating temperature indicated by the memory module 10.

It should be noted that the first preset value is a relatively small value. Therefore, the resistance value of the target resistor exhibits minimal variation between the normal temperature and a high temperature, thereby reducing an impact caused by the high temperature. Regardless of the normal temperature or the high temperature, the resistance values of the target resistor are close to each other, thereby implementing impedance matching, and maintaining high transmission performance and signal integrity.

For different types of memory modules 10, the second temperature may have different values, for example, 85° C., 100° C., or 125° C.

In some implementations, a difference between a resistance value of the target resistor at another temperature between the first temperature and the second temperature and the resistance value of the target resistor at the first temperature is also less than or equal to the first preset value.

In some embodiments, a value of the first preset value is: the resistance value of the target resistor at the first temperature×A, and a value range of A is 2% to 10%.

In an example, the first preset value=the resistance value of the target resistor at the first temperature×10%, that is, a fluctuation of the resistance value of the target resistor does not exceed 10% as a temperature varies.

In another example, the first preset value=the resistance value of the target resistor at the first temperature×5%, that is, a fluctuation of the resistance value of the target resistor does not exceed 5% as a temperature varies.

In still another example, the first preset value=the resistance value of the target resistor at the first temperature×2%. That is, a fluctuation of the resistance value of the target resistor does not exceed 2% as a temperature varies.

It should be noted that the signal ports 12 are at least allowed to be data ports and the data ports are configured to transmit data signals DQ. Herein, each of the memory chips 11 has multiple data ports, and a quantity depends on the bit width of the memory chip 11. For a 4-bit memory chip 11, there are four DQ ports. For an 8-bit memory chip 11, there are eight DQ ports. For a 16-bit memory chip 11, there are 16 DQ ports. For a 32-bit memory chip 11, there are 32 DQ ports. In addition, a quantity of memory chips 11 of one memory module 10 is large, and a transmission volume of data signals is large. Therefore, in a full-speed operation state, the series resistors on the signal lines of the data ports generate significant heat.

Therefore, in some embodiments, the foregoing target resistor is connected in series to the signal line between the memory chip 11 and each of the data ports. In this way, the resistance values of the target resistor at different temperatures are close to each other, so that the target resistor always operates based on an ideal operating parameter, thereby ensuring transmission integrity of the data signal DQ.

In addition, the signal ports 12 may further include one or more of a clock port, a command address port, and a data strobe port. Herein, the clock port is configured to transmit a clock signal CK, the command address port is configured to transmit a command address signal CA, and the data strobe port is configured to transmit a data strobe signal DQS.

In some embodiments, a signal line between the memory chip 11 and the clock port (and/or the command address port and/or the data strobe port) is also connected in series to a target resistor.

It should be noted that a quantity of clock ports, a quantity of command address ports, and a quantity of data strobe ports are limited, and a quantity of signals transmitted through these ports is also less than a quantity of signals transmitted through the data ports. Therefore, a heating problem is not serious. Therefore, in some other embodiments, the signal line between the memory chip 11 and the clock port (and/or the command address port and/or the data strobe port) does not need to be connected in series to the foregoing target resistor, but may be connected in series to a common surface-mount resistor or may not be connected in series to any resistor, thereby reducing a circuit area.

In some embodiments, referring to FIG. 4, the target resistor 13 includes a first resistor 131 and a second resistor 132 that are connected in parallel. A coefficient of variation of a resistance value of the first resistor 131 with a temperature is a positive value. A coefficient of variation of a resistance value of the second resistor 132 with a temperature is a negative value.

In this way, because the resistance value of the first resistor 131 increases as the temperature rises, and the resistance value of the second resistor decreases as the temperature rises, a fluctuation of a resistance value after the first resistor 131 and the second resistor are connected in parallel falls within an extremely small range, so that an overall resistance value remains unchanged within a tolerable error range, thereby compensating for an impact caused by temperature rising and improving transmission integrity of the data signal and impedance matching.

In some embodiments, the first resistor 131 may employ an original series resistor, that is, the resistance value of the first resistor 131 may provide good impedance matching at the normal temperature. In addition, a parameter of the second resistor 132 is selected based on a parameter of the first resistor 131.

In this case, conditions for selecting the second resistor 132 are as follows:
(1) The difference between the resistance value of the target resistor 13 at the first temperature and the resistance value of the target resistor 13 at the second temperature is less than or equal to the first preset value, that is, falls within a wide temperature range, and an equivalent resistance value of the target resistor 13 remains unchanged within the tolerable error range.
(2) A difference between the resistance value of the target resistor 13 and the resistance value of the first resistor 131 is less than or equal to a second preset value, that is, falls within a wide temperature range, and the equivalent resistance value of the target resistor 13 is approximately the same as the resistance value of the first resistor 131 within the tolerable error range.

In this way, the resistance value of the target resistor 13 is close to the resistance value of the original series resistor, thereby ensuring impedance matching. In addition, temperature variation is compensated for by the parameter of the second resistor 132, so that a fluctuation of the resistance value of the target resistor 13 is small within the wide temperature range, thereby ensuring signal integrity.

In an example, the second preset value=the resistance value of the first resistor 131 at the first temperature×B, and a value range of B is 1% to 5%.

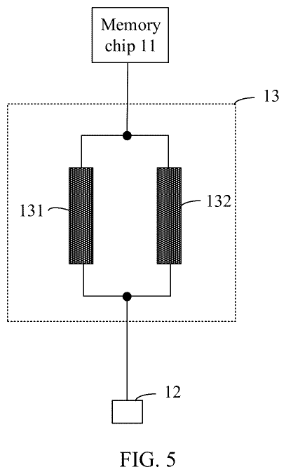

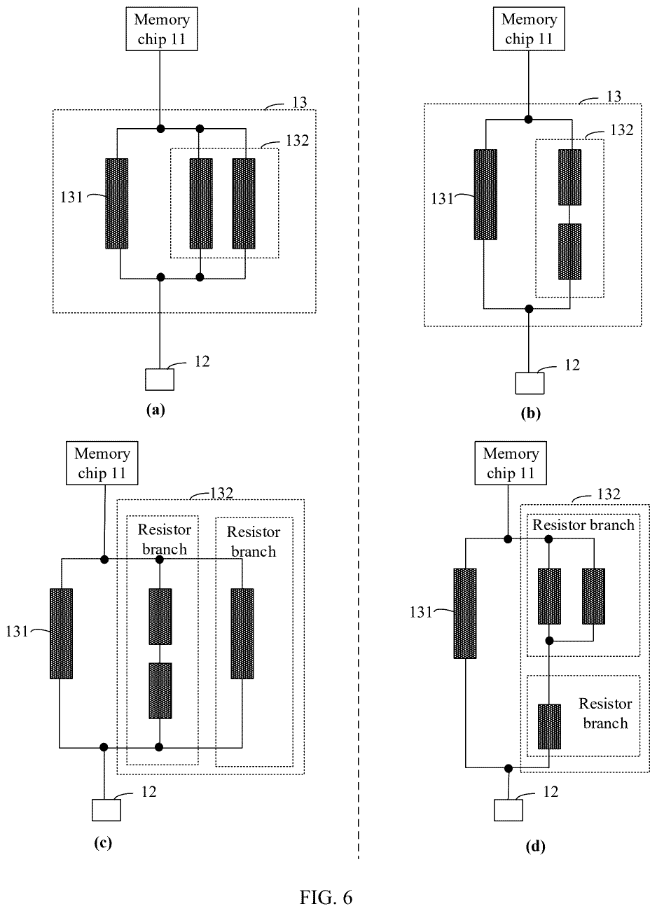

In a specific example, referring to FIG. 5, the second resistor 132 includes only one negative temperature coefficient resistor.

For example, the first resistor 131 may employ one or more of the following resistors: a surface-mount resistor, a thin-film resistor, a thick-film resistor, a metal film resistor, a metal oxide film resistor, a carbon film resistor, a wire wound resistor, a zero-ohm resistor, and an adjustable resistor. The surface-mount resistor is a surface-mount device, is widely applied to electronic devices, and has features of a small size, high precision, and a low temperature coefficient.

For example, the negative temperature coefficient resistor may employ an NTC thermistor, and the NTC thermistor is generally fabricated from metal oxides such as manganese, nickel, and cobalt.

For example, an absolute value of a temperature coefficient of the first resistor 131 is less than an absolute value of a temperature coefficient of the second resistor 132.

In this way, the temperature coefficient of the first resistor 131 is relatively small, and the resistance value exhibits small variation with a temperature, but the resistance value of the second resistor 132 is much greater than the resistance value of the first resistor 131, so that the first resistor 131 is configured to provide a main resistance value of the target resistor. The temperature coefficient of the second resistor 132 is relatively large, and the resistance value exhibits large variation with a temperature, so that the second resistor 132 is mainly configured to compensate for temperature variation caused by the first resistor 121.

In this case, that the second resistor 132 is a single NTC thermistor is taken as an example. In this case, the NTC thermistor needs to be selected based on the first resistor 131. A special operating temperature value (for example, the foregoing normal temperature or a maximum temperature) is selected for calculation, to ensure matching between operating extreme points of the NTC thermistor and the first resistor 131. For example, according to a formula (3), a range of a resistance value Rn₀ of the NTC thermistor at the normal temperature is calculated based on the resistance value R₀ of the first resistor 131 at the normal temperature and the second preset value R₀(1±B); and according to a formula (4), a range of a resistance value Rn₁ of the NTC thermistor at the second temperature is calculated based on the resistance value R₀ of the first resistor 131 at the normal temperature, the first preset value R₀(1±A), the second preset value R₀(1±B), and the resistance value R₁ of the first resistor 131 at the second temperature (for example, 100° C.). In addition, parameters Rn₀ and Rn₁ of the NTC thermistor further need to meet a formula (5), so that a required NTC thermistor is selected.

$${R}_{0} ( 1 - B ) \leq \frac{1}{( \frac{1}{{R}_{0}} + \frac{1}{R {n}_{0}} )} \qquad ( 3 )$$

$${R}_{0} ( 1 - B ) \leq \frac{1}{( \frac{1}{{R}_{1}} + \frac{1}{R {n}_{1}} )} \leq {R}_{0} ( 1 + B ) \qquad ( 4 )$$

$$\frac{1}{( \frac{1}{{R}_{0}} + \frac{1}{R {n}_{0}} )} ( 1 - A ) \leq \frac{1}{( \frac{1}{{R}_{1}} + \frac{1}{R {n}_{1}} )} \leq \frac{1}{( \frac{1}{{R}_{0}} + \frac{1}{R {n}_{0}} )} ( 1 + A ) \qquad ( 5 )$$

In a specific embodiment, at 25° C., the resistance value of the first resistor 131 is 15 ohms and the resistance value of the second resistor 132 is 1000 ohms; and at 100° C., the resistance value of the first resistor 131 is 17.5 ohms and the resistance value of the second resistor 132 is 85 ohms.

In this case, the resistance value of the target resistor 13 is 14.78 ohms at 25° C., representing variation of 1.46% compared with the resistance value (15Ω) of the first resistor 131 at 25° C. The resistance value of the target resistor 13 is 14.51 ohms at 100° C., representing variation of 3.25% compared with the resistance value (15 ohms) of the first resistor 131 at 25° C., and variation of 1.82% compared with the resistance value (14.78 ohms) of the target resistor 13 at 25° C. In this way, at different temperatures, the resistance value of the target resistor 13 does not vary greatly, and is close to the resistance value of the original series resistor, thereby maintaining good impedance matching, and improving signal transmission integrity.

In some other embodiments, the first resistor 131 may be a negative temperature coefficient resistor, the second resistor 132 may be a positive temperature coefficient resistor, and an absolute value of a temperature coefficient of the first resistor 131 is less than an absolute value of a temperature coefficient of the second resistor. In this case, a PTC thermistor, for example, a barium titanate material, may be selected for the second resistor 132.

In another specific example, the second resistor 132 includes multiple negative temperature coefficient resistors, and different resistors are connected in series and/or in parallel.

In still another specific example, the second resistor 132 includes a negative temperature coefficient resistor, a positive temperature coefficient resistor, and/or a fixed-value resistor, and different resistors are connected in series and/or in parallel.

In this way, because the coefficient of variation of the resistor with a temperature may be not ideal, the positive temperature coefficient resistor, multiple NTC thermistors with different temperature coefficients, and the fixed-value resistor are connected in series and/or in parallel to form the second resistor 132, so that matching and fitting can be performed at multiple temperatures, and the resistance value of the target resistor 13 can remain basically unchanged at the multiple temperatures, thereby better compensating for an impact caused by temperature variation, and improving signal transmission integrity.

For example, as shown in (a) of FIG. 6, the second resistor 132 includes multiple resistors connected in parallel.

In an example (1), the second resistor 132 includes multiple negative temperature coefficient resistors connected in parallel.

In an example (2), the second resistor 132 includes a negative temperature coefficient resistor and a positive temperature coefficient resistor that are connected in parallel, and a final temperature coefficient of the second resistor 132 is a negative value.

In an example (3), the second resistor 132 includes a negative temperature coefficient resistor and a fixed-value resistor that are connected in parallel.

In an example (4), the second resistor 132 includes a negative temperature coefficient resistor, a fixed-value resistor, and a positive temperature coefficient resistor that are connected in parallel.

As shown in (b) of FIG. 6, the second resistor 132 includes multiple resistors connected in series.

In an example (1), the second resistor 132 includes multiple negative temperature coefficient resistors connected in series.

In an example (2), the second resistor 132 includes a negative temperature coefficient resistor and a positive temperature coefficient resistor that are connected in series, and a final temperature coefficient of the second resistor 132 is a negative value.

In an example (3), the second resistor 132 includes a negative temperature coefficient resistor and a fixed-value resistor that are connected in series.

In an example (4), the second resistor 132 includes at least one negative temperature coefficient resistor, a fixed-value resistor, and a positive temperature coefficient resistor that are connected in series.

As shown in (c) of FIG. 6, the second resistor 132 includes multiple resistor branches connected in parallel, and each of the resistor branches includes several resistors connected in series.

Specific examples are as follows.

In an example (1), a resistor in a right resistor branch (a first branch) is a negative temperature coefficient resistor, and resistors in a left resistor branch (a second branch) are negative temperature coefficient resistors.

In an example (2), a resistor in a right resistor branch is a negative temperature coefficient resistor, and resistors in a left resistor branch are positive temperature coefficient resistors.

In an example (3), a resistor in a right resistor branch is a negative temperature coefficient resistor, and resistors in a left resistor branch are fixed-value resistors.

In an example (4), a resistor in a right resistor branch is a negative temperature coefficient resistor, and resistors in a left resistor branch are respectively a negative temperature coefficient resistor and a fixed-value resistor.

In an example (5), a resistor in a right resistor branch is a negative temperature coefficient resistor, and resistors in a left resistor branch are respectively a negative temperature coefficient resistor and a positive temperature coefficient resistor.

In an example (6), a resistor in a right resistor branch is a negative temperature coefficient resistor, and resistors in a left resistor branch are respectively a fixed-value resistor and a positive temperature coefficient resistor.

In an example (7), a resistor in a right resistor branch is a positive temperature coefficient resistor, and resistors in a left resistor branch are respectively a negative temperature coefficient resistor and a fixed-value resistor.

In an example (8), a resistor in a right resistor branch is a positive temperature coefficient resistor, and resistors in a left resistor branch are respectively a negative temperature coefficient resistor and a positive temperature coefficient resistor.

In an example (9), a resistor in a right resistor branch is a fixed-value resistor, and resistors in a left resistor branch are respectively a negative temperature coefficient resistor and a fixed-value resistor.

In an example (10), a resistor in a right resistor branch is a fixed-value resistor, and resistors in a left resistor branch are respectively a negative temperature coefficient resistor and a positive temperature coefficient resistor.

As shown in (d) of FIG. 6, the second resistor 132 includes resistor branches connected in series, and each of the resistor branches includes several resistors connected in parallel. Specific examples are as follows.

In an example (1), a resistor in a lower resistor branch (a first branch) is a negative temperature coefficient resistor, and resistors in an upper resistor branch (a second branch) are negative temperature coefficient resistors.

In an example (2), a resistor in a lower resistor branch is a negative temperature coefficient resistor, and resistors in an upper resistor branch are positive temperature coefficient resistors.

In an example (3), a resistor in a lower resistor branch is a negative temperature coefficient resistor, and resistors in an upper resistor branch are fixed-value resistors.

In an example (4), a resistor in a lower resistor branch is a negative temperature coefficient resistor, and resistors in an upper resistor branch are respectively a negative temperature coefficient resistor and a fixed-value resistor.

In an example (5), a resistor in a lower resistor branch is a negative temperature coefficient resistor, and resistors in an upper resistor branch are respectively a negative temperature coefficient resistor and a positive temperature coefficient resistor.

In an example (6), a resistor in a lower resistor branch is a negative temperature coefficient resistor, and resistors in an upper resistor branch are respectively a fixed-value resistor and a positive temperature coefficient resistor.

In an example (7), a resistor in a lower resistor branch is a positive temperature coefficient resistor, and resistors in an upper resistor branch are respectively a negative temperature coefficient resistor and a fixed-value resistor.

In an example (8), a resistor in a lower resistor branch is a positive temperature coefficient resistor, and resistors in an upper resistor branch are respectively a negative temperature coefficient resistor and a positive temperature coefficient resistor.

In an example (9), a resistor in a lower resistor branch is a fixed-value resistor, and resistors in an upper resistor branch are respectively a negative temperature coefficient resistor and a fixed-value resistor.

In an example (10), a resistor in a lower resistor branch is a fixed-value resistor, and resistors in an upper resistor branch are respectively a negative temperature coefficient resistor and a positive temperature coefficient resistor.

In the foregoing description, the fixed-value resistor refers to a resistor whose resistance value exhibits small variation with a temperature, for example, a surface-mount resistor.

In this way, resistors of different types that have different parameters are combined, to more precisely adjust a performance curve of the second resistor 132, so that the resistance value of the target resistor 13 can remain basically unchanged at multiple temperatures.

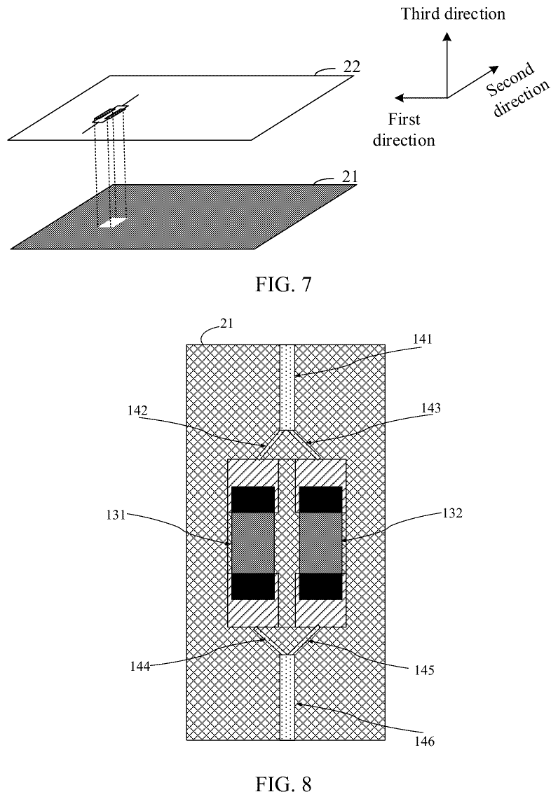

It should be noted that in this embodiment of the present disclosure, the second resistor 132 is introduced into the target resistor 13 to compensate for the impact caused by temperature rising on the first resistor 131. However, introduction of the second resistor 132 may lead to an increase in ground capacitance. Therefore, in some embodiments, referring to FIG. 7, the memory module 10 includes a reference ground layer 21 and a signal trace layer 22. The reference ground layer 21 and the signal trace layer 22 are arranged in a third direction, and the third direction is perpendicular to a plane of a substrate of the memory chips 11. The foregoing signal lines are located in the signal trace layer 22, a hollowed region exists in the reference ground layer 21, and a projection of the target resistor 13 in the third direction falls within the hollowed region.

In this way, referring to FIG. 8, which is a top view of the memory module 10. In the reference ground layer, a part opposite to the target resistor 13 is hollowed out, to avoid adding additional ground capacitance, and avoid a negative impact on the memory module 10.

In some embodiments, referring to FIG. 8, each of the signal lines is divided into a first main line 141, a second branch line 142, a third branch line 143, a fourth branch line 144, a fifth branch line 145, and a sixth main line 146. A first end of the first main line 141 is connected to the memory chip 11, a second end of the first main line 141 is connected to a first end of the second branch line 142 and a first end of the third branch line 143, a second end of the second branch line 142 is connected to a first end (corresponding welding block) of the first resistor 131, a second end of the third branch line 143 is connected to a first end (corresponding welding block) of the second resistor 132, a first end of the fourth branch line 144 is connected to a second end (corresponding welding block) of the first resistor 131, a second end of the fifth branch line 145 is connected to a second end (corresponding welding block) of the second resistor 132, a second end of the fourth branch line 144 and a second end of the fifth branch line 145 are connected to a first end of the sixth main line 146, and a second end of the sixth main line 146 is connected to the data port.

It should be understood that the second resistor 132 is located beside the first resistor 131. As shown in FIG. 8, the second resistor 132 is located on a right side of the first resistor 131. However, actually, the second resistor 132 may alternatively be located on a left side of the first resistor 131. Within a process-tolerable range, it is preferable for the two resistors to be as close as possible to reduce the circuit area and shorten a trace length.

In addition, in the accompanying drawings, the size of the first resistor 131 is the same as that of the NTC thermistor, which is merely an example and does not constitute a specific limitation.

Both the first resistor 131 and the second resistor 132 are welded to a circuit board. FIG. 8 further shows welding blocks.

In some embodiments, as shown in FIG. 8, the width of the first main line 141 is the same as the width of the sixth main line 146, the second branch line 142, the third branch line 143, the fourth branch line 144, and the fifth branch line 145 have the same width, and the width of the first main line 141 is greater than the width of the second branch line 142.

In this way, the branch lines are thin and have high impedance, so that impedance of the branch lines connected in parallel approximates impedance of the original signal line to maintain stable signal transmission.

In addition, a connection manner of the branch lines shown in FIG. 8 is merely an example and does not constitute a related limitation. An angle between the branch lines has no special significance. If necessary, the branch lines can also be configured in an L-shape.

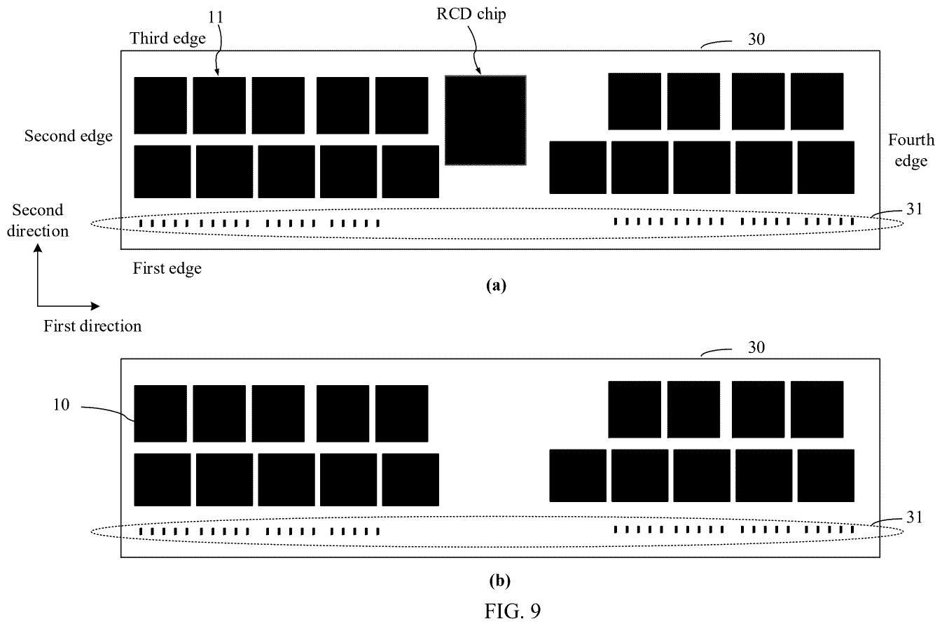

Referring to (a) of FIG. 9, which shows a schematic diagram of a frontside structure of a memory module 30 in a related solution. Referring to (b) of FIG. 9, which shows a schematic diagram of a backside structure of a memory module 30 in a related solution.

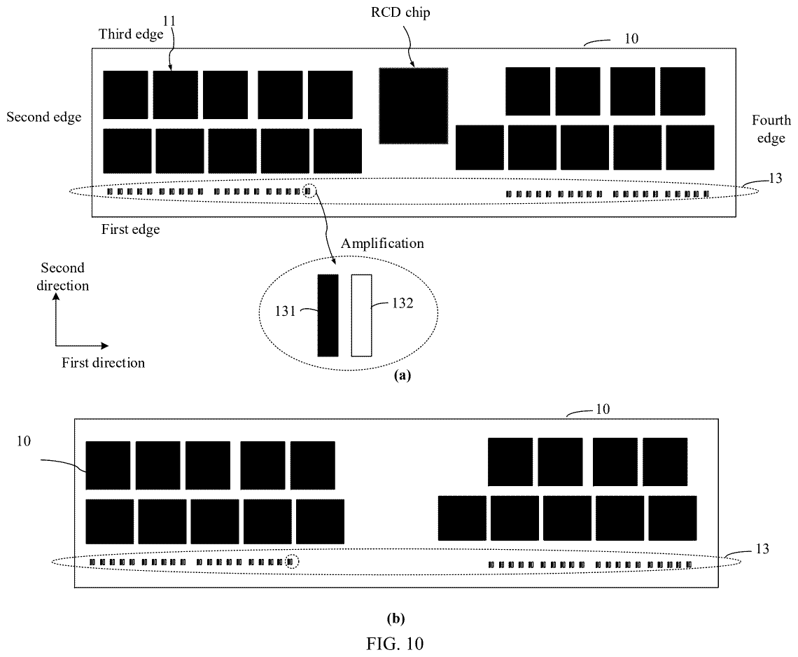

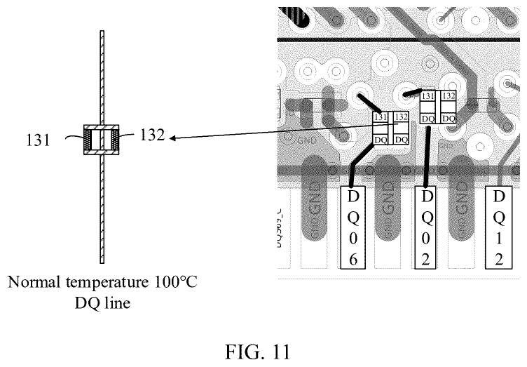

Referring to (a) of FIG. 10, which shows a schematic diagram of a frontside structure of a memory module 10 according to an embodiment of the present disclosure. Referring to (b) of FIG. 10, which shows a schematic diagram of a backside structure of a memory module 10 according to an embodiment of the present disclosure.

Basic structures of the memory module 10 and the memory module 30 are similar. To be specific, the memory module 10 includes a first region, RCD chips, and a second region that are sequentially arranged in the first direction. 10 memory chips 11 are distributed in the first region, and 9 memory chips 11 are distributed in the second region. Two opposite edges of the memory module 30 in the second direction are respectively referred to as a first edge and a third edge, and two opposite edges of the memory module 30 in the first direction are respectively referred to as a second edge and a fourth edge. The length of the memory module 30 along the first edge is greater than the length of the memory module 10 along the second edge. All the data ports are arranged in parallel in the first direction, and the data ports are disposed close to the first edge.

Herein, each of the RCD chips may be referred to as a register clock driver (Register Clock Driver) with main functions of signal buffering, clock signal distribution, signal enhancement, and loading reduction, and is an important module in the RDIMM. In addition, there is no need to dispose the RCD chips for an unbuffered DIMM.

Referring to FIG. 9, there are series resistors 31 on the signal lines between the memory chips 11 and the data ports, and multiple series resistors 31 are arranged in parallel in the first direction and are close to the first edge of the memory module 30.

Referring to FIG. 10, there are target resistors 13 on the signal lines between the memory chips and the data ports, and each of the target resistors 13 includes a first resistor 131 and an NTC thermistor (equivalent to a second resistor 132) that are connected in parallel. Multiple target resistors 13 are arranged in parallel in the first direction, and are close to the first edge of the memory module 30. The first resistor 131 and the second resistor 132 are arranged in parallel in the first direction.

Referring to FIG. 11, which is a schematic diagram of a back side of a circuit board of a memory module 10. As shown in FIG. 11, the second resistor 132 is disposed close to the first resistor 131. Within a tolerable range, it is preferable for the two resistors to be as close as possible.

In addition, for FIG. 10, only the signal line of the data port is connected in series to the target resistor 13 formed by connecting the first resistor 131 to the NTC thermistor in parallel. Such a design is not performed for another port such as a clock port or a command address port.

The following shows test data for the foregoing two circuit structures.

For the memory module 30 shown in FIG. 9, that is, in a case in which only a series resistor (with a resistance value of 15 (at a normal temperature, and a resistance value of 17.5 ohms at 100° C.) is disposed on the data signal line but a negative temperature coefficient resistor is not disposed:

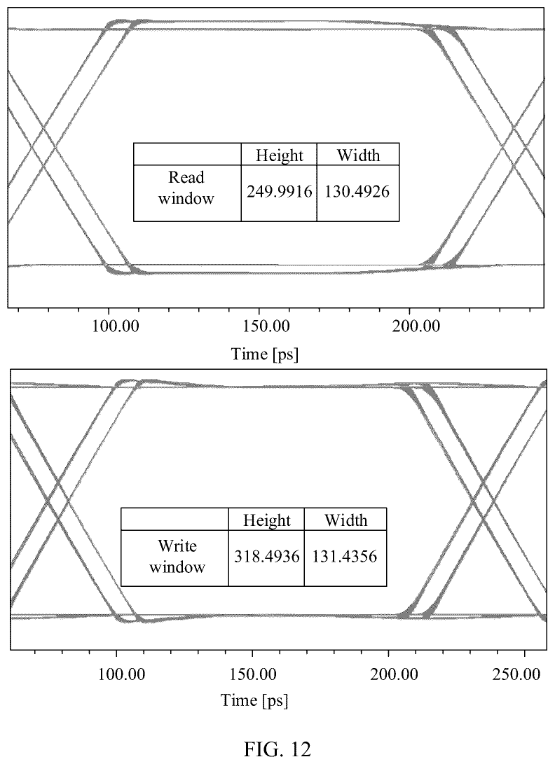

Referring to FIG. 12, which is an eye diagram of signal transmission in a read operation and a write operation of the memory module 30 at 25° C., the height of a read window is 249.9916, and the width is 130.4926. (b) is an eye diagram of signal transmission in a write operation of the RDIMM module at 100° C. The height of a write window is 318.49, and the width is 131.4356.

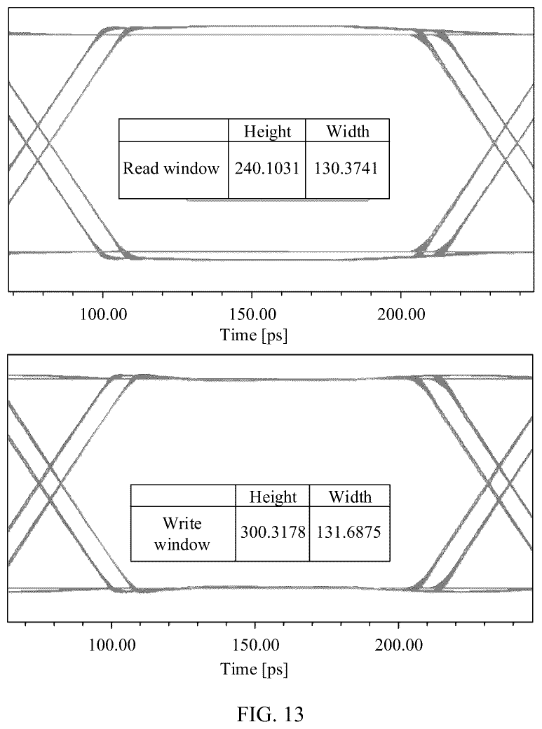

Referring to FIG. 13, which is an eye diagram of signal transmission in a read operation and a write operation of the memory module 30 at 100° C., the height of a read window is 240.1031 and the width is 130.3741, and the height of a write window is 300.6178 and the width is 131.6875.

It may be learned from comparison between FIG. 12 and FIG. 13 that, at 100° C., both the height of the read window and the height of the write window are significantly reduced compared with those at 25° C. Therefore, signal integrity may be affected, causing a data reception/transmission error.

For the memory module 10 shown in FIG. 10, that is, in a case in which a target resistor (a first resistor+an NTC thermistor) is disposed on a signal line, at 25° C., the resistance value of the first resistor is 15Ω and the resistance value of the NTC thermistor is 1000Ω, and at 100° C., the resistance value of the first resistor is 17.5Ω and the resistance value of the NTC thermistor is 85Ω:

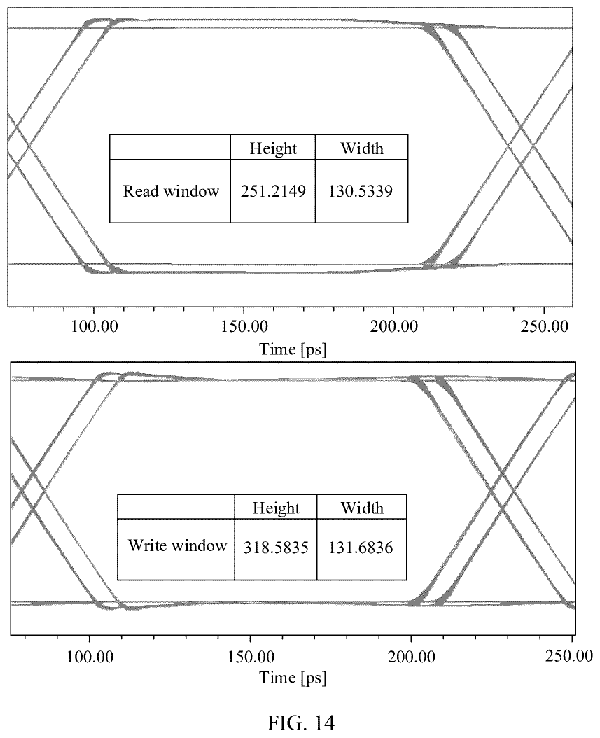

Referring to FIG. 14, which is an eye diagram of signal transmission in a read operation and a write operation of the memory module 10 at 25° C., the height of a read window is 251.2149 and the width is 130.5339, and the height of a write window is 318.5836 and the width is 131.6836.

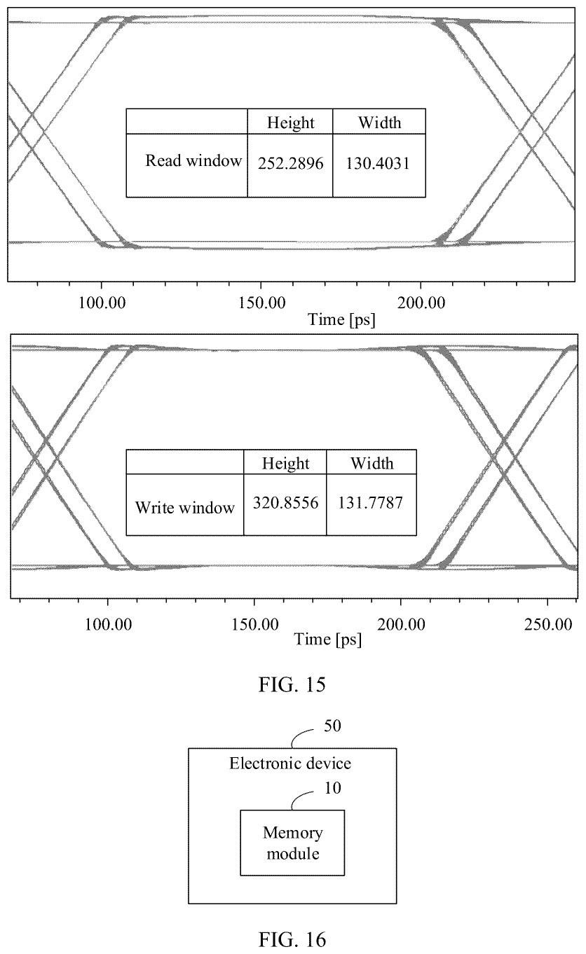

Referring to FIG. 15, which is an eye diagram of signal transmission in a read operation and a write operation of the memory module 30 at 100° C., the height of a read window is 252.2896 and the width is 130.4031, and the height of a write window is 320.8556 and the width is 131.7787.

It may be learned from comparison between FIG. 14 and FIG. 15 that, at 100° C., both the height of the read window and the height of the write window remain basically unchanged compared with those at 25° C. Therefore, signal integrity is good, and correctness of data reception/transmission is ensured.

In addition, it may be learned from comparison between FIG. 12 and FIG. 14 that, at the normal temperature, signal transmission performance of the two circuits is similar. It may be learned from comparison between FIG. 13 and FIG. 15 that, at a high temperature, the heights of both the read window and the write window of the memory module 10 provided in this embodiment of the present disclosure significantly increase, thereby improving signal transmission integrity.

In conclusion, the present disclosure mainly relates to the series resistors on the signal lines in the RDIMM, and in particular, to transmission integrity of the data signals and a thermal effect of a substrate material and metal lines. The thermistors are additionally connected in parallel to compensate for the impact caused by temperature rising on the original series resistors. Therefore, the present disclosure is applied to signal trace design on the RDIMM or another similar DDR structure.

Specifically, for the RDIMM, when a quantity of memory chips 10 is large, if an operating rate is high, the signal lines for data signal transmission generate significant heat, and an overall temperature of the RDIMM rises. Temperature rising mainly leads to two consequences: first, a decrease in characteristic impedance of the signal traces; and second, an increase in direct current resistance of both the original series resistors and the traces. This causes signal integrity to be damaged at the high temperature compared to that implemented at the normal temperature.

For the foregoing problems, in this embodiment of the present disclosure, an NTC thermistor (equivalent to the second resistor 32) is connected in parallel to the original series resistor (equivalent to the first resistor 131) to improve this case. In addition, for the entire DIMM, this processing is mainly performed on a DQ single-ended signal line because the DQ single-ended line has a high rate and is greatly affected by impedance variation. Therefore, this processing does not need to be performed on a CA signal line, a CK signal line, and a DQS signal line.

In addition, after the NTC thermistor is connected in parallel, because the thermistor may cause an increase in the ground capacitance, a lower reference ground of the two resistors needs to be hollowed, and traces connected to two pads need to be thinned, that is, line impedance is increased. In addition, the NTC thermistor is located beside the original series resistor. A main principle is that it is preferable for the two resistors to be as close as possible within a process-tolerable range. Referring to FIG. 8, left-right positional arrangement between the NTC thermistor and the original series resistor is not limited and may be determined based on an available space. This processing is performed on each DQ single-ended signal line on the RDIMM. The thermistor may be selected based on an application scenario. Under normal ambient temperature variation conditions, a maximum temperature value of the DIMM is below 100° C., making a 1000-ohm NTC thermistor a good choice.

In an extreme environment, the resistance value of the NTC thermistor may be increased or decreased based on a specific condition.

In another embodiment of the present disclosure, referring to FIG. 16, which is a schematic diagram of a compositional structure of an electronic device 50 according to an embodiment of the present disclosure. As shown in FIG. 16, the electronic device 50 includes at least the foregoing memory module 10.

The memory module 10 includes multiple memory chips 11 and multiple groups of signal ports 12, and each of the memory chips 11 implements signal input and output through a corresponding group of signal ports 12. The memory chip 11 is electrically connected to each of the signal ports 12 through an independent signal line, that is, an input/output port of the memory chip 11 is connected to a corresponding signal port 12 through the signal line, and some or all signal lines are connected in series to target resistors. A difference between a resistance value of each of the target resistors at a first temperature and a resistance value of the target resistor at a second temperature is less than or equal to a first preset value. The first temperature is a normal temperature, and the second temperature is a maximum value of an operating temperature indicated by the memory module 10.

Therefore, the resistance value of the target resistor exhibits minimal variation between the normal temperature and a high temperature, thereby reducing an impact caused by the high temperature. Regardless of the normal temperature or the high temperature, the resistance values of the target resistor are close to each other, thereby implementing impedance matching, and maintaining high transmission performance and signal integrity.

The foregoing descriptions are merely specific implementations of the present disclosure, but are not intended to limit the protection scope of the present disclosure. Any variation or replacement readily figured out by a person skilled in the art within the technical scope disclosed in the present disclosure shall fall within the protection scope of the present disclosure. Therefore, the protection scope of the present disclosure shall be subject to the protection scope of the claims.

What is claimed is:

1. A memory module, comprising a plurality of memory chips and a plurality of groups of signal ports, each of the memory chips implementing signal input and output through a corresponding group of signal ports;
the memory chip being electrically connected to each of the signal ports through an independent signal line, and some or all signal lines being connected in series to target resistors; and
a difference between a resistance value of each of the target resistors at a first temperature and a resistance value of the target resistor at a second temperature being less than or equal to a first preset value, the first temperature being a normal temperature, and the second temperature being a maximum value of an operating temperature indicated by the memory module.

2. The memory module according to claim 1, wherein each of the target resistors comprises a first resistor and a second resistor that are connected in parallel;
a coefficient of variation of a resistance value of the first resistor with a temperature is a positive value; and
a coefficient of variation of a resistance value of the second resistor with a temperature is a negative value.

3. The memory module according to claim 2, comprising a reference ground layer and a signal trace layer, the reference ground layer and the signal trace layer being arranged in a third direction, and the third direction being perpendicular to a plane of a substrate of the memory chips; and
the signal line being located in the signal trace layer, a hollowed region existing in the reference ground layer, and a projection of the target resistor in the third direction falling within the hollowed region.

4. The memory module according to claim 2 wherein
the second resistor comprises one negative temperature coefficient resistor.

5. The memory module according to claim 2, wherein
the second resistor comprises a plurality of negative temperature coefficient resistors, and different resistors are connected in series and/or in parallel.

6. The memory module according to claim 2, wherein
the second resistor comprises a negative temperature coefficient resistor, a positive temperature coefficient resistor, and/or a fixed-value resistor, and different resistors are connected in series and/or in parallel.

7. The memory module according to claim 4, wherein
the first resistor is a surface-mount resistor, and the negative temperature coefficient resistor is an NTC thermistor; and
a difference between the resistance value of the target resistor and the resistance value of the first resistor at the first temperature is less than or equal to a second preset value.

8. The memory module according to claim 2, wherein
the signal ports comprise data ports, the signal line between the memory chip and each of the data ports is connected in series to the target resistor.

9. The memory module according to claim 8, wherein the signal line is divided into a first main line, a second branch line, a third branch line, a fourth branch line, a fifth branch line, and a sixth main line;
a first end of the first main line is connected to the memory chip, a second end of the first main line is connected to a first end of the second branch line and a first end of the third branch line, a second end of the second branch line is connected to a first end of the first resistor, a second end of the third branch line is connected to a first end of the second resistor, a first end of the fourth branch line is connected to a second end of the first resistor, a second end of the fifth branch line is connected to a second end of the second resistor, a second end of the fourth branch line and a second end of the fifth branch line are connected to a first end of the sixth main line, and a second end of the sixth main line is connected to the data port; and
a width of the first main line is same as a width of the sixth main line, the second branch line, the third branch line, the fourth branch line, and the fifth branch line have a same width, and the width of the first main line is greater than the width of the second branch line.

10. The memory module according to claim 1, wherein
the memory module is a registered dual in-line memory module;
the memory chip is a dynamic random access memory chip; and
a value of the first preset value is: the resistance value of the target resistor at the first temperature×A, and a value range of A is 2% to 10%.

11. An electronic device, comprising the memory module according to claim 1.
